(19) United States
(12) Patent Application Publication
(10) Pub. No.: US 2007/0284594 A1
(43) Pub. Date: Dec. 13, 2007

(54) Light emitting diode chip

(75) Inventors: Masayoshi Koike, Gyunggi-Do (KR); Bum Joon Kim, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/730,791

(22) Filed: Apr. 4, 2007

(30) Foreign Application Priority Data
Apr. 21, 2006 (KR) 10-2006-36372

(51) Int. Cl. H01L 27/15

(52) U.S. Cl. 257/87; 257/E27.12

(57) ABSTRACT

A light emitting diode (LED) chip including: a substrate; and a light emitting structure including a first conductive semiconductor layer, an active layer, and a second conductive semiconductor layer, sequentially deposited on the substrate, in which when a length of the substrate is L and a width of the substrate is W, L/W>10.

### CLAIM OF PRIORITY

This application claims the benefit of Korean Patent Application No. 2006-0036372 filed on Apr. 21, 2006, in the Korean Intellectual Property Office, the disclosure of which is incorporated herein by reference.

### BACKGROUND OF THE INVENTION

1. Field of the Invention

The present invention relates to a light emitting diode (LED), and more particularly, to an LED chip having high light emitting efficiency.

2. Description of the Related Art

Recently, LEDs using one of III-V family and II-VI family compound semiconductor materials have been used in light emitting devices for visible light and have been applied as a light source of various kinds of products such as electric signs, lightings, and LCD backlights. To manufacture semiconductor LEDs, a light emitting structure is formed by sequentially depositing an n type semiconductor layer, an active layer, and a p type semiconductor layer on a substrate.

The shape of a plane of general LED chip is a square, or similar to a square such as 0.3 mm×0.3 mm and 1 mm×1 mm. Also, considering efficiency of emitting light, the amount of light emitted from sides of a substrate of an LED chip is considerable. When considerable amount of light are emitted from a top surface of a LED chip or a bottom surface of a substrate, namely, the LED chip is not a type of emitting light from one surface, the amount of the light emitted from the sides of the substrate occupies considerable parts of total amount of light emitted from the entire of the LED chip. Since a ratio of the size of the sides to a light emitting size decreases as the size of a LED chip increases in the case of a square type LED chip, the efficiency of emitting light also decreases.

FIG. 1A is a perspective view illustrating a square type LED chip 10, and FIG. 1B is a view illustrating the chip 10 mounted on a submount 20. Referring to FIG. 1A, the LED chip 10 includes an n type semiconductor layer 13, an active layer 15, and a p type semiconductor layer 17. A p-side electrode 18 and an n-side electrode 19 are formed on a top surface of the p type semiconductor layer 17 and a bottom surface of the substrate 11, respectively. The substrate 11 is a conductive substrate such as GaN, and the LED chip 10 is formed in the shape of a vertical structure. FIGS. 1A and 1B reversely illustrating the LED chip 10 having the described configuration. Namely, the bottom surface of the substrate 11 is a light output surface and turns upward and the p-side electrode 18 turns downward and is bonded to the submount 20. When the LED chip is mounted on the submount 20 as shown in FIG. 1B, light is emitted from a top surface, namely, the bottom surface of the substrate 11 and sides of the LED chip 10. In this case, the amount of the light emitted from the sides occupies considerable parts of the total amount of the light emitted from the top surface and the sides of the LED chip 10.

In the conventional square type LED chip 10, a length L of the LED chip 10, namely, a length of the substrate 11 is identical with or similar to a width W of the LED chip 10. Accordingly, the size L×W of the LED chip becomes L² and a ratio of the size 4tL of the sides to the size L² of emitting light becomes 4t/L. In this case, t indicates thickness of the LED chip 10. Accordingly, as the size of the LED chip 10 increases or L increases, the ratio of the size of the sides to the size of an area emitting light decreases. Accordingly, as the size of the LED chip 10 or the size of the emitting light increases, the efficiency of emitting light decreases. When the size of chips increases to obtain greater light flux or to be applied to high power LEDs, the problem of deterioration of the efficiency of emitting light may become worse.

On the other hand, in an LED of AlGaInN series, when a wavelength of emitting light is more than 450 nm, the higher current density the lower external quantum efficiency (EQE). FIG. 2 is a graph illustrating a change of EQE depending on current density in an LED chip of InGaN series, whose size is 0.9 mm×0.9 mm. In this case, a wavelength of emitting light is 450 nm. Referring to FIG. 2, the lower current density, the higher EQE. Accordingly, a large size LED driven in low current density has an advantage in quantum efficiency. However, as described above, since the efficiency of emitting light decreases as the size of an LED chip increases, improvement of EQE due to size enlargement may be reduced by reduction of emitting light, namely, reduction of the ratio of the size of sides of a chip.

### SUMMARY OF THE INVENTION

An aspect of the present invention provides an LED chip advantageous to embody a large size LED having high efficiency and having more improve d light emitting efficiency.

According to an aspect of the present invention, there is provided a light emitting diode (LED) chip including: a substrate; and a light-emitting structure including a first conductive semiconductor layer, an active layer, and a second conductive semiconductor layer, sequentially deposited on the substrate, wherein when a length of the substrate is L and a width of the substrate is W, L/W>10. L/W may be more than 20.

A bottom surface of the substrate and sides of the LED chip may be main light output surfaces. L may be more than 5 mm and W may be less than 500 μm. The first conductive semiconductor layer may be n type semiconductor and the second conductive semiconductor layer may be p type semiconductor. The substrate may be formed of a material selected from a group consisting of GaN, SiC, GaAs, GaP, ZnO, and sapphire. The first conductive semiconductor layer, the active layer, and the second conductive semiconductor layer may be formed of III family nitride semiconductor.

The LED chip may be a vertical type. In this case, the LED chip may further include: a first electrode formed on the bottom surface of the substrate; and a second electrode formed on the second conductive semiconductor layer to opposite to the first electrode. The first electrode may include a pad portion and at least one line portion extended lengthwise to the LED chip. The first electrode may include: two line portions extended lengthwise to the LED chip; and a pad portion disposed between the two line portions and connecting the two line portions. In this case, the bottom surface of the substrate may be the light output surface.

The LED chip may be a horizontal type. In this case, the LED chip may further include: a first electrode formed on a part of the first conductive semiconductor layer; and a second electrode formed on the second-conductive semiconductor layer, in which the first electrode and the second electrode may be disposed on the same side of the LED chip. The LED chip may be a flip chip. In this case, the bottom surface of the substrate may be the light output surface.

In the present specification, III family nitride semiconductor indicates one of binary, ternary, and quaternary compound semiconductors shown as AlₓGa_{y}In_{(1-x-y)}N (0≦x≦1, 0≦y≦1, 0≦x+y≦1). A length of an LED chip is identical with a length of a substrate and indicates a length of the longest of sides of the substrate of the LED chip. A width of the LED chip is identical with a width of the substrate and indicates a length of the shortest of sides of the substrate of the LED chip.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are perspective views illustrating a conventional LED chip;

FIG. 2 is a graph illustrating a change of EQE, depending on current density in the conventional LED chip;

FIG. 3 is a perspective view illustrating an LED chip according to an exemplary embodiment of the present invention;

FIG. 4A is a top view illustrating the LED chip of FIG. 3;

FIG. 4B is a back view illustrating the LED chip of FIG. 3;

FIG. 5 is cross-sectional view illustrating the LED chip of FIG. 3 mounted on a reflecting cup of a package;

FIG. 6 is a perspective view illustrating an LED chip according to an exemplary embodiment of the present invention;

FIG. 7 is a graph illustrating normalized EQE according to the size of samples of the LED chip according to an exemplary embodiment and comparison examples;

FIG. 8 is a graph illustrating EQE depending on the size of the LED chip according to an exemplary embodiment and the LED chip as an example;. and

FIG. 9 is a graph illustrating EQE according to the sum of lengths of sides of the LED chip.

### DETAILED DESCRIPTION OF THE PREFERRED EMBODIMENT

Exemplary embodiments of the present invention will now be described in detail with reference to the accompanying drawings.

FIG. 3 is a perspective view illustrating an LED chip 100 according to an exemplary embodiment of the present invention. Referring to FIG. 3, the LED chip 100 includes an n type semiconductor layer 103, an active layer 105, and a p type semiconductor layer 107, which are sequentially deposited on a GaN substrate 101. The n type semiconductor layer 103, the active layer 105, and the p type semiconductor layer 107 are III family nitride semiconductors mounted on the GaN substrate 101 and form a light emitting structure 150. An n-side electrode 110 is formed on a bottom surface A of the GaN substrate 101, and a p-side electrode 108 is formed on a top surface B of the p type semiconductor layer 107. The LED chip 100 is formed in the shape of a vertical LED structure including the n-side electrode 110 and the p-side electrode 108 opposite to each other and the light emitting structure 150 interposed therebetween.

Referring to FIG. 3, a length L of the substrate 101 is longer than a width W of the substrate 101. Particularly, the length L is longer than the width W more than ten times. Namely, L>10W or L/W>10. Since the length L is much longer than the width W, the LED chip 100 is thin and long. The thin and long LED chip 100 increases the amount of emitting light from sides of the LED chip 100 and improves efficiency of emitting light.

When the LED chip 100 is mounted on a submount and operates, the bottom surface A of the substrate 101 and sides of the LED chip 100 operate as a main light output surface. Namely, referring to arrows in FIG. 3, a large portion of light is emitted via the bottom surface A of the substrate 101 and sides of the LED chip 100. Since the bottom surface A becomes light output surface, when the LED chip 100 is mounted on the submount, the bottom surface A is disposed upward. Accordingly, to prevent light emitted from the substrate 101 from being absorbed or shaded by the n-side electrode 110, the size of the n-side electrode 110 has to be small enough. On the other hand, since the top surface B of the p type semiconductor layer 107 turns toward a mounting surface of the submount, actually, the top surface B does not emit light. Since the p-side electrode 108 is attached to the mounting surface of the submount, the p-side electrode 108 may have the size large enough. To acquire an effect of light reflection by using the p-side electrode 108, the p-side electrode 108 may have a high reflection rate.

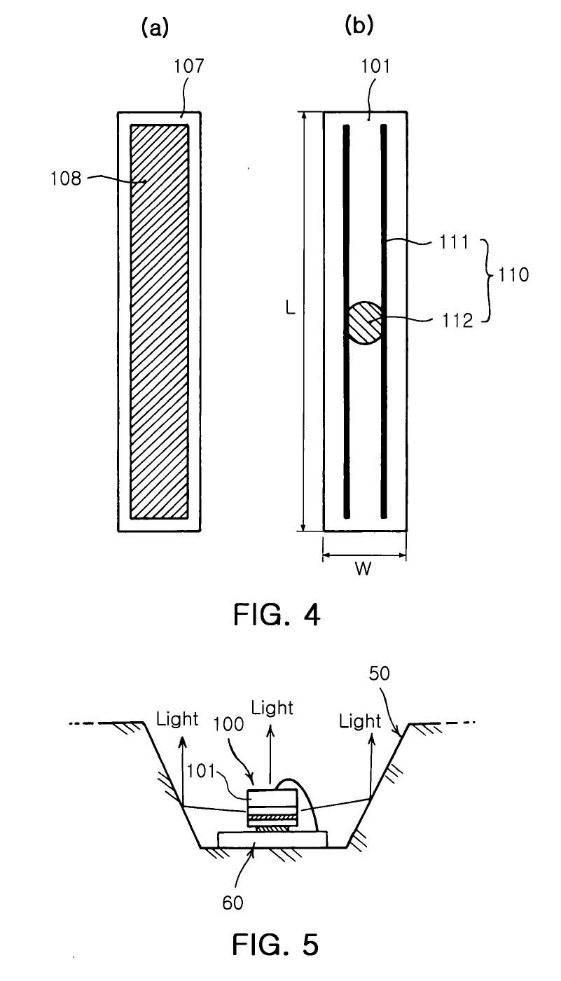

FIGS. 4A and 4B are a top view and a back view illustrating the LED chip 100 of FIG. 3, respectively. Referring to FIG. 4A, the p-side electrode 108 is applied to a large part of the top surface of the p type semiconductor layer 107. However, referring to FIG. 4B, the n-side electrode 110 is applied to a small part of the bottom surface of the GaN substrate 101 to allow the bottom surface to be exposed enough. In detail, the n-side electrode 110 includes two line portions 111 extended lengthwise to the length L of the LED chip 100 and a pad portion 112 connecting the two line portions 111. Therefore, blocking light emission due to the n-side electrode 110 may be reduced. Also, the line portions 111 extended long are disposed right and left, voltage may be applied to the entire of the GaN substrate 101 and current may be distributed to control concentration of current.

FIG. 5 is a cross-sectional view illustrating the LED chip 100 mounted on a submount 60. Referring to FIG. 5, the bottom surface of the GaN substrate 101, which is a light output surface, is disposed upward, and the p-side electrode 108 is bonded to a mounting surface of the submount 60. For example, a chip may be bonded by using one of cream solder and eutectic bonding. A reflecting cup 50 is installed around the submount 60 to reflect light emitted from sides upward.

According to the LED chip 100 described referring to FIGS. 3 through 5, reduction of light emitting efficiency, caused by increase of a chip size, may be controlled. This is, in the case of the same size of chips, a thin and long chip has an advantage over a square type chip in light emitting efficiency. Namely, a chip whose length is longer than a width thereof has an advantage over a chip whose length is identical with a width thereof. Particularly, when L/W>10, high light emitting efficiency may be acquired. This is caused by a considerable amount of light emitted from sides of an LED chip. Herein after, it will be described in detail as follows.

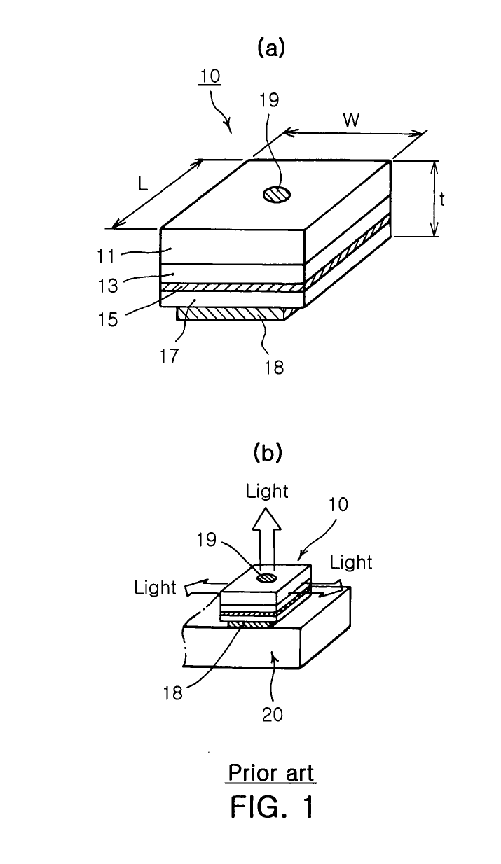

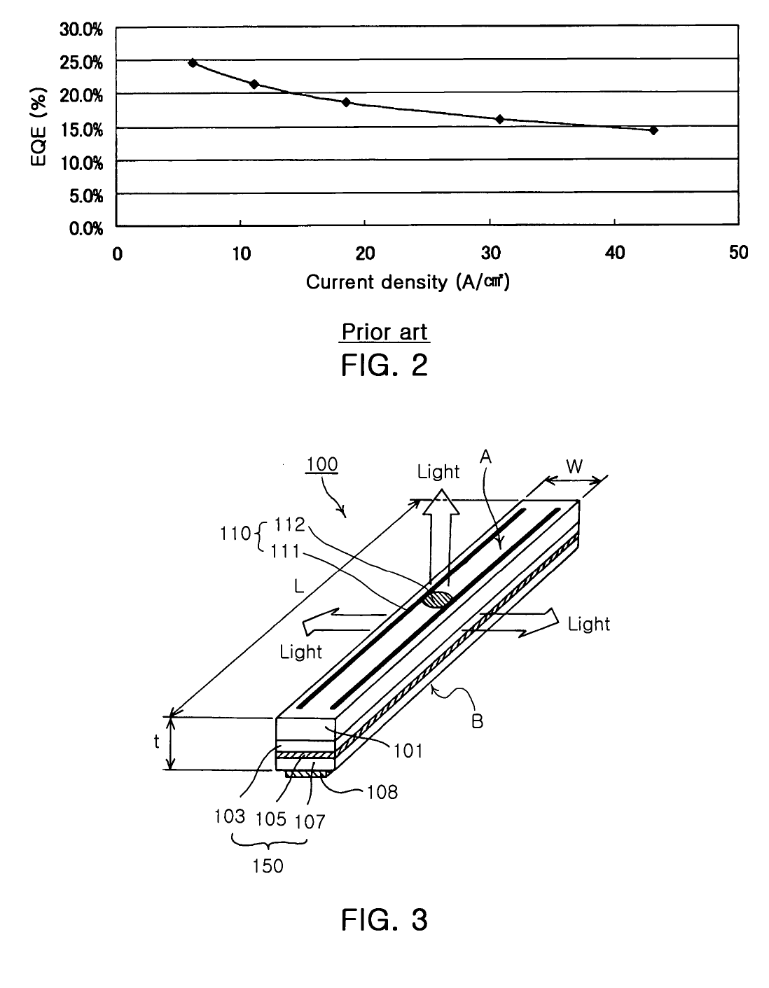

In the case of photons generated in an active layer, the larger size a photon has, the better emitted outside the photon is. Accordingly, as a factor for determining light emitting efficiency of an LED chip, a ratio of the entire size of a light output surface to the size of an active layer may be considered.

$$k = \frac{entiresizeoflightemissionsurface}{sizeoflightemission} = \frac{2 t ( L + W )}{LW} \qquad Equation 1$$

in which t indicates the thickness of an LED chip, L indicates the LED chip, and W indicates a width of the LED chip (refer to one of FIG. 1 and FIG. 3). Since the size of light emission is equal to the size of a bottom surface of a substrate, the size of light emission becomes LW. Also, since light is emitted from a top surface and sides of an LED chip mounted on a submount and excludes a bottom surface attached to the submount, the entire size of the light output surface becomes 2tL+2tW+LW.

When L is identical with or similar to W as a conventional square type LED chip (refer to FIG. 1), a factor of light emitting efficiency may be shown as follows.

$$k = \frac{2 t ( L + W ) + LW}{LW} = \frac{4 t L + {L}^{2}}{{L}^{2}} = \frac{4 t}{L} + 1 \qquad Equation 2$$

Accordingly, in the conventional square type LED chip, the larger size the chip has, the smaller k is. Particularly, when thickness t is hardly changed, k decreases and converges to 1 as L increases to infinity ∞. Actually, with respect to a large size LED chip driven in a low current density, L has a value much larger than a value of t.

However, when L is longer than W, and more particularly, L is longer than W more than ten times, k is shown as follows.

$$k = \frac{2 t ( L + W ) + LW}{LW} = \frac{2 t}{L} + \frac{2 t}{W} + 1 \qquad Equation 3$$

Accordingly, though L has a large value as a large size LED chip, k does not converge to 1 by a second term 2t/W of equation. Particularly, in the same size of light emission, the larger L/W becomes, the smaller W becomes. Therefore, though the size of chips are the same, the larger ratio of L to W L/W is, the better light emitting efficiency is. Improvement of the light emitting efficiency of the LED chip according to an exemplary embodiment of the present invention may be confirmed via graphs of FIGS. 7 through 9 that will be described later. To satisfy the condition of L/W>10, L may be more than 5 mm and W may be less than 500 μm.

Though a GaN substrate is used as the substrate 101 in the above, the present invention will not be limited to the GaN substrate and may employ another conductive substrate that can embody a vertical type LED. For example, the substrate 101 may be formed of one selected from a group consisting of SiC, GaAs, GaP, and ZnO.

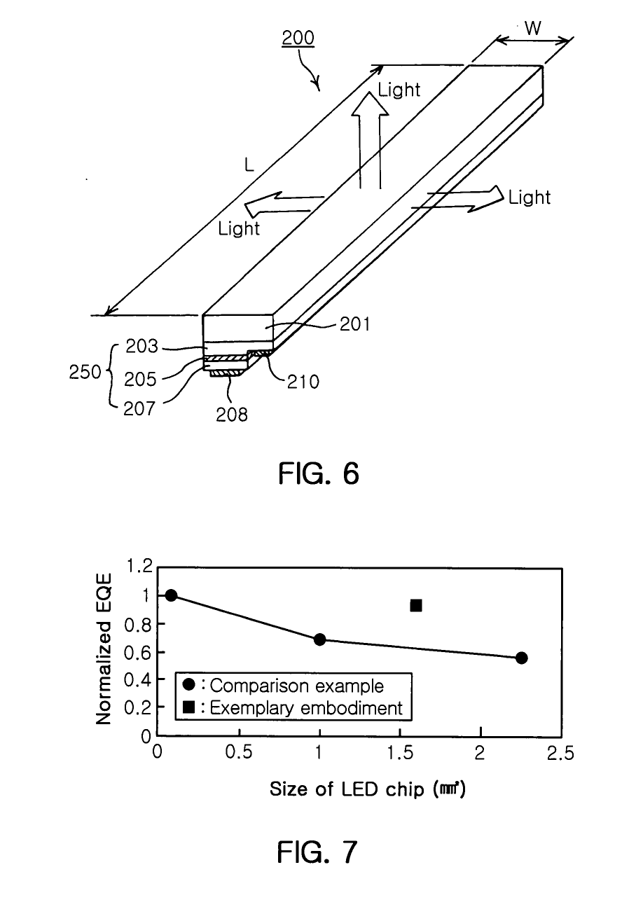

FIG. 6 is a perspective view illustrating an LED chip 200 according to an exemplary embodiment of the present invention. The LED chip 200 corresponds to a horizontal type LED chip, different from the LED chip 100 shown in FIG. 3. Namely, an n-side electrode 210 and a p-side electrode 208 are disposed at the same side of the LED chip 200. Referring to FIG. 6, the LED chip 200 includes an n type semiconductor layer 203, an active layer 205, and a p type semiconductor layer 207, sequentially deposited on a substrate 201 of sapphire. The n type semiconductor layer 203, the active layer 205, and the p type semiconductor layer 207 form a light emitting structure 250 of the LED chip 200. The n-side electrode 210 is formed on a part of then type semiconductor 203 exposed by mesa etching, and the p-side electrode 208 is formed on the p type semiconductor 207.

Similar to the LED chip 100, in the LED chip 200, a bottom surface of the substrate 201 emits light, together with sides of the substrate 201. Accordingly, as shown in FIG. 6, the LED chip 200 is mounted on a submount (not shown) as a top and a bottom of the LED chip are changed. Namely, the n-side electrode 210 and the p-side electrode are flip-chip bonded to the submount via appropriate bump. Accordingly, the LED chip 200 corresponds to a flip-chip.

As shown FIG. 6, a length L of the LED chip 200 is longer than a width W of the LED chip 200 and a ratio L/W of the length L to the width W is more than 10. Accordingly, the LED chip 200 is a long thin shape. Since the ratio L/W has a value more than 10 in the vertical type LED chip 200, the amount of emitting light from the sides of the LED chip 200 increases. Accordingly, light emitting efficiency is greater than a conventional square type LED chip.

To check an effect of the ratio L/W on EQE When a size LW of an LED chip increases, EQE with respect to conventional square type LED chip samples and a sample of the LED chip according to an exemplary embodiment of the present invention are measured. The result of measurement is shown in FIG. 7.

FIG. 7 is a graph illustrating normalized EQE according to the size of samples of the LED chip according to an exemplary embodiment of the present invention and a conventional square type LED chip. The EQE shown in FIG. 7 is measured in current density of 35 A/cm². The samples shown in FIG. 7 are prepared as follows.

In FIG. 7, the samples of the conventional LED chip have three different sizes. The samples of the conventional LED chip are square type chips of 0.3×0.3 mm (0.92 mm²), 1×1 mm (1 mm²), and 1.5×1.5 mm (2.25 mm²), respectively (refer to FIG. 1). The size of chips, namely, the size of an area emitting light is shown in parentheses of the respective sizes.

On the other hand, the LED chip of an exemplary embodiment of the present invention is 0.4×5 mm (2.0 mm²). The length L of the LED chip is 5 mm and the width W of the LED chip is 0.4 mm, and L/W corresponds to 12.5. The size of the p-side electrode is 0.36×4.96 mm, and the size of the n-side has two lines of 0.15×3.96 mm, respectively (refer to FIG. 4). The samples of the LED chips employ a GaN substrate whose thickness is 0.2 mm. The samples of the LED chips are a vertical type LED chip formed of III family nitride semiconductors of AlGaInN series.

As shown in FIG. 7, normalized EQE of the samples of the square type LED chip decreases as the size of the chip increases. However, the normalized EQE of the long thin chip is shown higher than EQE of the samples of the square type LED chip. As described above, this is caused by increase of the amount of light emitted from the sides.

As described above, as the size of the chip increases, the LED chip according to an exemplary embodiment of the present invention has a more advantage in light emitting efficiency. When the length of the chip is longer than the width of the chip more than ten times, regardless of increase of the size of the chip, deterioration of the light emitting efficiency and EQE is effectively controlled. Accordingly, the LED chip according to an exemplary embodiment of the present invention is advantageous in application to a large area of low current density.

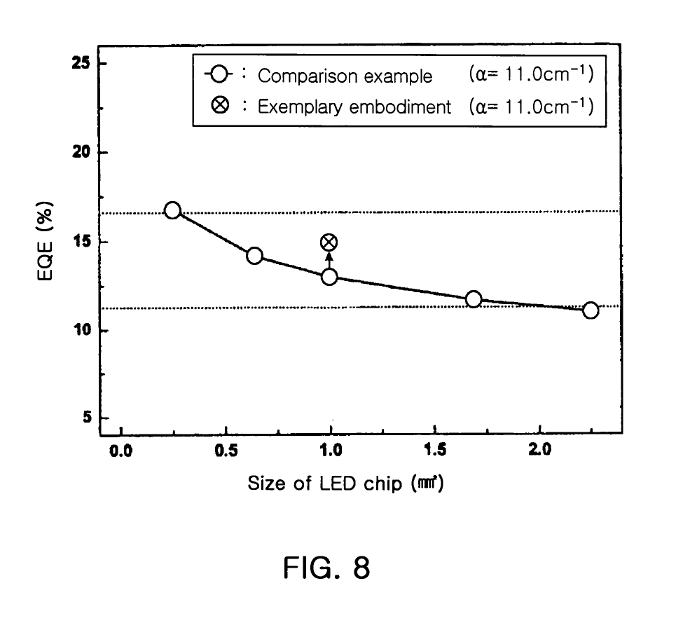

FIG. 8 is a graph illustrating a result of another simulation experiment. In FIG. 8, EQE according to the size of LED chips according to an exemplary embodiment and comparison examples. In this simulation experiment, EQE is calculated by assuming that an absorption coefficient a is 11.0 cm⁻¹. In details, samples of the comparison example are a conventional square type LED chips, namely, L=W and have an absorption coefficient of 11.0 cm⁻¹. On the other hand, a sample of the LED chip according to an exemplary embodiment is an LED chip of 0.1×10 mm and has an absorption coefficient of 11.0 cm⁻¹.

As shown in FIG. 8, as the size of the square type LED chip increases, EQE decreases. However, EQE is higher when L/W>10, for example, L=10 mm and W=0.1 mm, than when L/W=1, for example, L=1 mm and W=1 mm. Namely, though the chip size is the same, a chip that L/W>10 may acquire notably improved EQE. Arrows in FIG. 8 visually show an EQE improvement effect.

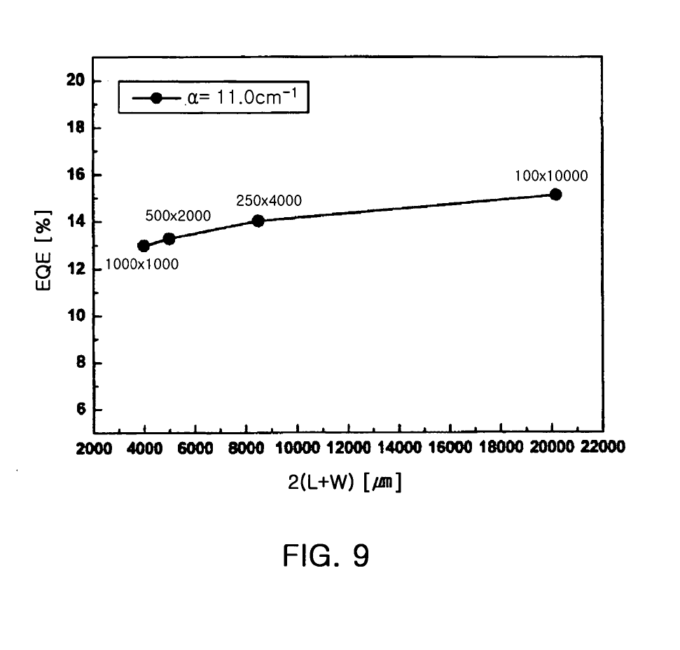

FIG. 9 is a graph illustrating EQE according to the sum of lengths of sides of an LED chip. Table 1 illustrates each point indicating a regulation of an LED chip sample and EQE of each sample in FIG. 9.

TABLE 1

| | | Sum of lengths of |
|---|---|---|
| Regulation of chip | | sides of chip |
| W (mm) × L (mm) | EQE (%) | (2 W + 2 L) (mm) |
| 0.10 × 10.0 (1 mm²) | 15.10 | 20.2 |
| 0.25 × 4.0 (1 mm²) | 14.03 | 8.5 |
| 0.50 × 2.0 (1 mm²) | 13.29 | 5.0 |
| 1.0 × 1.0 (1 mm²) | 12.98 | 4.0 |

As shown in FIG. 9 and Table 1, when the sizes of chips are the same, for example, W×L=1 mm², EQE more increases as entire length (2L +2W) of four sides of the chip increases. Namely, when values of W×L are the same, the EQE more increases as L increases, namely, L/W increases. This is because the amount of light emitted from the sides of the chip may more increase as L/W increases, as described above.

As described above, according to an exemplary embodiment of the present invention, an high quality high efficiency LED chip satisfying L/W>10, having light emitting efficiency notably more improved than a conventional square type LED chip, and having an advantage in application to high efficiency large area may be embodied.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting diode (LED) chip comprising:
a substrate; and
a light emitting structure including a first conductive semiconductor layer, an active layer, and a second conductive semiconductor layer, sequentially deposited on the substrate,
wherein when a length of the substrate is L and a width of the substrate is W, L/W>10.

2. The LED chip of claim 1, wherein L/W>20.

3. The LED chip of claim 1, wherein a bottom surface of the substrate and sides of the LED chip are main light output surfaces.

4. The LED chip of claim 1, wherein L is more than 5 mm and W is less than 500 μm.

5. The LED chip of claim 1, wherein the first conductive semiconductor layer is n type semiconductor and the second conductive semiconductor layer is p type semiconductor.

6. The LED chip of claim 1, wherein the substrate is formed of a material selected from a group consisting of GaN, SiC, GaAs, Gap, ZnO, and sapphire.

7. The LED chip of claim 1, wherein the first conductive semiconductor layer, the active layer, and the second conductive semiconductor layer are formed of III family nitride semiconductor.

8. The LED chip of claim 1, further comprising:
a first electrode formed on the bottom surface of the substrate; and
a second electrode formed on the second conductive semiconductor layer to be opposite to the first electrode.

9. The LED chip of claim 8, wherein the first electrode comprises a pad portion and at least one line portion extended lengthwise to the LED chip.

10. The LED chip of claim 9, wherein the first electrode comprises:
two line portions extended lengthwise to the LED chip; and
a pad portion disposed between the two line portions and connecting the two-line portions.

11. The LED chip of claim 1, further comprising:
a first electrode formed on a part of the first conductive semiconductor layer; and
a second electrode formed on the second conductive semiconductor layer,
wherein the first electrode and the second electrode are disposed on the same side of the LED chip.

12. The LED chip of claim 11, the LED chip is a flip chip.
